(19) United States
(12) Patent Application Publication
(10) Pub. No.: US 2002/0113295 A1
(43) Pub. Date: Aug. 22, 2002

(54) Semiconductor device and method for its manufacture

(76) Inventor: Ryoichi Nakamura, Tokyo (JP)

Correspondence Address: Darryl G. Walker, WALKER & SAKO, LLP, 300 South First Street, Suite 235, San Jose, CA, 95113, US

(21) Appl. No.: 10/040,076

(22) Filed: Oct. 26, 2001

(30) Foreign Application Priority Data
Oct. 30, 2000 (JP) 2000-331450

(51) Int. Cl. H01L 23/58

(52) U.S. Cl. 257/640

(57) ABSTRACT

A semiconductor device is disclosed including a memory cell region (I) and a peripheral region (II). The memory cell region (I) may have a more densely arranged gate spacing than the peripheral region (II). The memory cell region (I) may include an interlayer insulating film (206) and peripheral region (II) may include an interlayer insulating film (208). The interlayer insulating film (208) in the peripheral region (II) may have a lower concentration of boron and phosphorus than the interlayer insulating film (206) in the memory cell region (I). The concentration of boron in the interlayer insulating film (208) in the peripheral region (II) may be less than 11 mole percent and the concentration of phosphorus may be less than 6 mole percent. In this way, boron and phosphorus may be prevented from diffusing into the substrate while filling properties of the interlayer insulating film may be sufficient.

### TECHNICAL FIELD

The present invention relates generally to a semiconductor device and method for its manufacture, and more specifically to a semiconductor device including an insulating film formed on a densely arranged memory cell region and a method for manufacturing such a semiconductor device.

### BACKGROUND OF THE INVENTION

A semiconductor device having a multi-layered wiring structure such as a DRAM includes an interlayer insulating film in order to electrically isolate wiring layers. Boron phosphorus silicate glass (BPSG) is widely used for the interlayer insulating film.

Referring now to FIG. 2, a cross-sectional diagram of a conventional semiconductor device after various processing steps is set forth.

Conventional semiconductor device includes a silicon substrate 301, gate oxide film 302, gate DOPOS (doped polysilicon) film 303, gate WSi 304, nitride film 305, interlayer BPSG film 306, oxide film 307, shallow trench isolation (STI) 309, and side-wall 310.

Referring further to FIG. 2, a region to the left of the dotted line is a memory cell region I where a gate interval is dense. A region to the right of the dotted line is a peripheral region II where a gate interval is coarse. In the peripheral region II driving transistors are disposed. The transistors in the memory cell region I have a gate length (width of gate DOPOS 303) of 0.15 μm with an adjacent gate interval of 0.15 μm. The transistors in the peripheral region II have a gate length (width of gate DOPOS 303) of 0.25 μm with an adjacent gate interval of 0.5 μm.

The conventional semiconductor device is adapted to include interlayer BPSG film 306 having the same predetermined concentration in both the memory cell region I and the peripheral region II.

A process flow for the conventional semiconductor device will now be described. Manufacture of the conventional semiconductor device includes gate formation, side-wall formation of a transistor in the peripheral region, and a formation of a low concentration BPSG interlayer insulating film, in this order.

Referring now to FIG. 1, a cross-sectional diagram of a conventional semiconductor device after various processing steps is set forth. The cross-sectional diagram illustrates the conventional semiconductor device after the formation of side-wall.

A gate oxide film of 7 nm is formed by thermal oxidation of silicon substrate 301. The silicon substrate 301 includes shallow trench isolation (STI) 309 for device isolation. A gate DOPOS film 303 having a thickness of 100 nm is formed with a low-pressure chemical vapor deposition (LP-CVD) method. Then, gate WSi film 204 having a thickness of 100 nm is formed with a chemical vapor deposition (CVD) method.

Thereafter the gate is patterned by photolithography and etching processes.

After the gate patterning, memory cell region I and peripheral region II are subjected to ion implantation under proper conditions to form lightly doped drain (LDD) regions for each transistor (not shown).

Referring still to FIG. 1, the formation of the side-wall 310 of the transistors in the peripheral region II will now be discussed.

A nitride film 305 is formed over the surface. Then, in the peripheral region II, the nitride film is subjected to photolithography and etched back using an anisotropic dry etching method. In this way, a gate side-wall 310 is formed in the peripheral region II.

After the formation of the gate-side wall 310, n-type metal oxide semiconductor (NMOS) transistors and p-type metal oxide semiconductor (PMOS) transistors with proper conditions to form a source and drain for each transistor (not shown).

Referring once again to FIG. 2, the formation of a low concentration BPSG interlayer insulating film for the conventional semiconductor device will now de discussed.

The conventional semiconductor device includes a silicon substrate 301, gate oxide film 302, gate DOPOS (doped polysilicon) film 303, gate WSi 304, nitride film 305, interlayer BPSG film 306, oxide film 307, shallow trench isolation (STI) 309, and side-wall 310. On these films, a 10 nm thick oxide film 307 is deposited with a normal pressure CVD method. Thereafter, a 500 nm thick BPSG film 306 is deposited with normal pressure TEOS (tetraethyl orthosilicate) CVD method.

The BPSG film 306 has a boron concentration of 8 mole percent and a concentration of phosphorus of 4.5 mole percent.

Thereafter, BPSG film 306 is reflowed by being subjected to a heat treatment of 800° C.

Although not illustrated, a planarizing process using CMP (chemical mechanical polishing) is performed. Then contacts, wiring, and storage capacitors are formed. In this way, a conventional dynamic random access memory (DRAM) is constructed.

In the memory cell region I, the gate interval is continuously made finer in order to improve the manufacturing costs. However, in the aforementioned conventional manufacturing method, use is made of a BPSG interlayer insulating film having the same concentrations of boron and phosphorus in both the memory cell region I and peripheral region II of a DRAM. This fails to adequately satisfy the insulating film filling property or embedding property.

For improving the filing property, a method for forming a high concentration BPSG film is used. However, it is necessary in the peripheral region to construct a drain of a driving transistor as an LDD structure by forming a gate side-wall nitride film 205 by etching. This eliminates a diffusion stopper, which serves to prevent boron and phosphorus in the BPSG film from diffusing into the substrate. The conventional approach thus has the drawback that if a high concentration BPSG is used for the interlayer insulating film, boron and phosphorus undergo outdiffusion into the substrate which can cause device characteristics (such as transistors) to vary.

Japanese Laid-Open Patent Publications No. Hei 10-116899, No. Hei 10-4140, and No. Hei 04-269853 disclose a BPSG film used as an interlayer insulating film and constructed as a double layer structure. The double layer structure has a low concentration PSG film used as a first layer and a high concentration BPSG film used as a second layer. This may suppress the diffusion of impurities and provide proper filling properties of the BPSG film of the second layer. However, because the first layer is a low concentration BPSG film, filling properties using this layer may be deteriorated.

In light of the above discussion, it would be desirable to provide a semiconductor device which may include an interlayer insulating film in the memory cell region having an improved filling property. It would also be desirable to provide an interlayer insulating film in the memory cell region of a semiconductor device without boron and phosphorus diffusing from the interlayer insulating film into the substrate.

### SUMMARY OF THE INVENTION

A semiconductor device according to the present embodiments may include a memory cell region and a peripheral region. The memory cell region may have a more densely arranged gate spacing than the peripheral region. The memory cell region may include an interlayer insulating film and peripheral region may include an interlayer insulating film. The interlayer insulating film in the peripheral region may have a lower concentration of boron and phosphorus than the interlayer insulating film in the memory cell region. The concentration of boron in the interlayer insulating film in the peripheral region may be less than approximately 1 mole percent and the concentration of phosphorus may be less than approximately 6 mole percent. In this way, boron and phosphorus may be prevented from diffusing into the substrate while filling properties of the interlayer insulating film may be sufficient.

According to one aspect of the embodiments, a semiconductor device may include a memory cell region having a plurality of first gates and a first gate interval. A peripheral region may have a plurality of second gates and a second gate interval. The first gate interval may be denser than the second gate interval. A nitride film may be formed on the memory cell region including the plurality of first gates. A memory cell region interlayer insulating film may be formed on the memory cell region including the nitride film. A peripheral region interlayer insulating film may be formed on the peripheral region. The memory cell region interlayer insulating film may have a higher concentration of boron and phosphorus than the peripheral region interlayer insulating film.

According to another aspect of the embodiments, the concentration of boron in the peripheral region interlayer insulating film may be approximately 11 mole percent or less.

According to another aspect of the embodiments, the concentration of phosphorus in the peripheral region interlayer insulating film may be approximately 6 mole percent or less.

According to another aspect of the embodiments, the concentrations of boron and phosphorus in the memory cell interlayer insulating film may be approximately 1.3 to 1.8 times the concentrations of boron and phosphorus in the peripheral region interlayer insulating film.

According to another aspect of the embodiments, the memory cell region interlayer insulating film may fill spaces between the plurality of first gates. The peripheral region interlayer insulating film may fill spaces between the plurality of second gates.

According to another aspect of the embodiments, the plurality of second gates may include side-wall structures.

According to another aspect of the embodiments, the plurality of first gates and the plurality of second gates may include a doped polysilicon film.

According to another aspect of the embodiments, a method for manufacturing a semiconductor device may include the steps of patterning a gate on a substrate so that a first gate interval in a memory cell region may be more densely arranged than a second gate interval in a peripheral region, forming a nitride film on the gates, forming a high dopant concentration interlayer insulating film on the nitride film, removing at least portions of the nitride film and the high dopant concentration interlayer insulating film in the peripheral region, and forming a low dopant concentration interlayer insulating film in the memory cell region and the peripheral region. The low dopant concentration interlayer insulating film may have a lower dopant concentration than the high dopant concentration interlayer insulating film.

According to another aspect of the embodiments, removing at least portions of the nitride film and the high dopant concentration interlayer insulating film may include masking the high impurity concentration interlayer insulating film in the memory cell region.

According to another aspect of the embodiments, the method for manufacturing the semiconductor device may include the step of flattening the high dopant concentration interlayer insulating film and low dopant concentration interlayer insulating film to provide surfaces of the high dopant concentration interlayer insulating film and low dopant concentration interlayer insulating film that are essentially flush with each other.

According to another aspect of the embodiments, the high dopant concentration interlayer insulating film may have a concentration of boron that is approximately 11 mole percent or higher.

According to another aspect of the embodiments, the low dopant concentration interlayer insulating film may have a concentration of phosphorus that is approximately 6 mole percent or higher.

According to another aspect of the embodiments, the low dopant concentration interlayer insulating film may have a concentration of boron that may be approximately 11 mole percent or less.

According to another aspect of the embodiments, the low dopant concentration interlayer insulating film may have a concentration of phosphorus that may be approximately 6 mole percent or less.

According to another aspect of the embodiments, a semiconductor device may include a first region having a plurality of first gates and a first gate interval. A second region having a plurality of second gates and a second gate interval. The first gate interval may be smaller than the second gate interval. A nitride film may be formed on the first region including the plurality of first gates. A first region interlayer insulating film may be formed on the first region including the nitride film. A second region interlayer insulating film may be formed on the second region. The first region interlayer insulating film may have a higher dopant concentration than the second region interlayer insulating film.

According to another aspect of the embodiments, the concentration of boron in the second region interlayer insulating film may be approximately 11 mole percent or less.

According to another aspect of the embodiments, the concentration of phosphorus in the second region interlayer insulating film may be approximately 6 mole percent or less.

According to another aspect of the embodiments, the concentration of boron in the first region interlayer insulating film may be approximately 11 mole percent or more.

According to another aspect of the embodiments, the concentration of phosphorus in the first region interlayer insulating film may be approximately 6 mole percent or more.

According to another aspect of the embodiments, the concentrations of boron and phosphorus in the first region interlayer insulating film may be approximately 1.3 to 1.8 times the concentrations of boron and phosphorus in the second region interlayer insulating film.

### BRIEF DESCRIPTION OF THE DRAWINGS

FIG. 1 is a cross-sectional diagram of a conventional semiconductor device after various processing steps.

FIG. 2 is a cross-sectional diagram of a conventional semiconductor device after various processing steps.

FIG. 3 is a cross-sectional view of a portion of a semiconductor device after various processing steps according to an embodiment.

FIG. 4 is a cross-sectional view of a portion of a semiconductor device after various processing steps according to an embodiment.

FIG. 5 is a cross-sectional view of a portion of a semiconductor device after various processing steps according to an embodiment.

FIG. 6 is a cross-sectional view of a portion of a semiconductor device after various processing steps according to an embodiment.

FIG. 7 is a cross-sectional view of a portion of a semiconductor device after various processing steps according to an embodiment.

FIG. 8 is a cross-sectional view of a portion of a semiconductor device after various processing steps according to an embodiment.

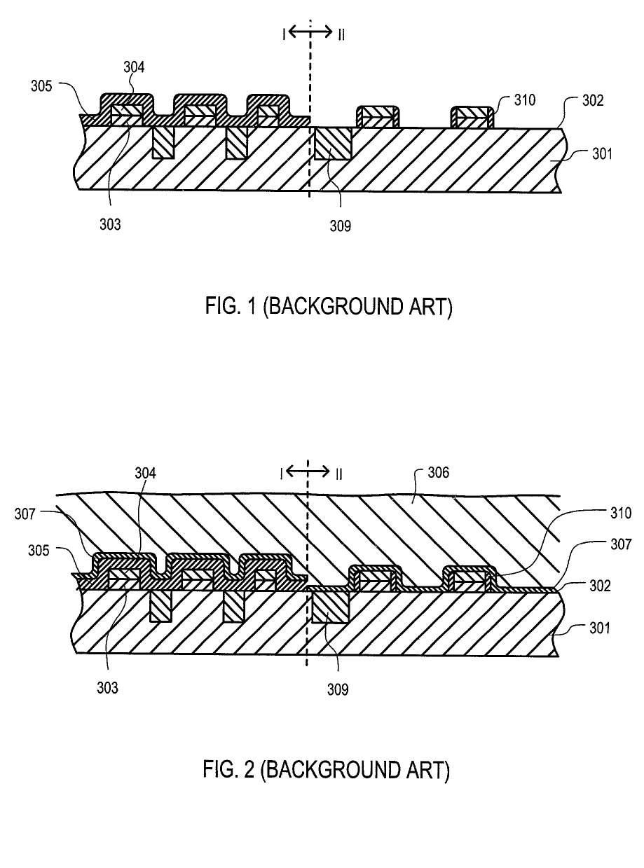

### DETAILED DESCRIPTION OF THE EMBODIMENTS

Various embodiments of the present invention will now be described in detail with reference to a number of drawings.

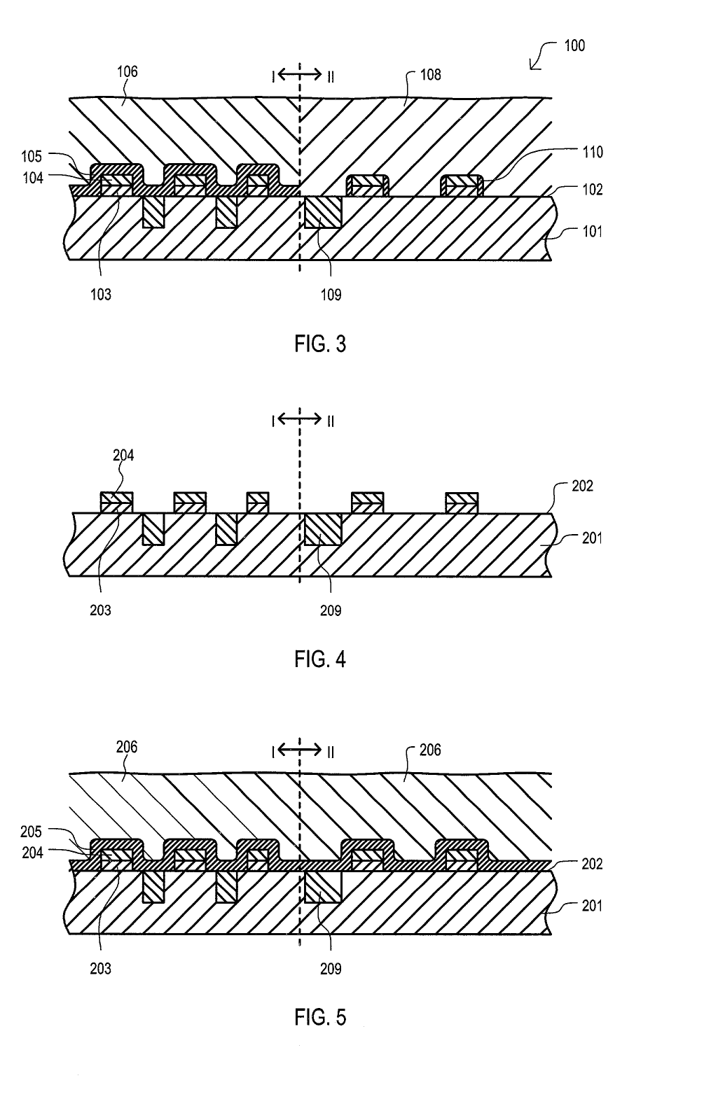

Referring now to FIG. 3, a cross-sectional view of a portion of a semiconductor device after various processing steps according to an embodiment is set forth and given the general reference character 100.

Semiconductor device 100 may have a memory cell region I to the left of the dashed line and a peripheral region II to the right of the dashed line. Semiconductor device 100 includes a silicon substrate 101, gate oxide film 102, gate DOPOS (doped polysilicon) film 103, gate WSi 104, nitride film 105, and side-wall 110. Semiconductor device 100 may also include an interlayer insulating film 106 in memory cell region I and interlayer insulating film 108 in peripheral region II.

Silicon substrate 101 may be subject to a step for forming shallow trench isolation (STI) 109 for providing device isolation. Such devices may include gate DOPOS film 103 and WSi film 106 formed on a gate oxide film 102.

Memory cell region I in the present embodiment may include gates (gate DOPOS film 103 and WSi film 106) that are densely patterned on the surface of the silicon substrate 101.

Gate intervals in the memory cell region I may include a gate length (width of gate DOPOS 103 in the memory cell region I) of approximately 0.15 μm with an adjacent gate interval of approximately 0.15 μm. Gate intervals in the peripheral region II may include a gate length (width of gate DOPOS 103 in the peripheral region II) of approximately 0.25 μm with an adjacent gate interval of approximately 0.5 μm.

A nitride film 105 may be formed between the gates of memory cell region I and the interlayer insulating film 106. Interlayer insulating film 106 may include a film of boron phosphorus silicate glass (BPSG), for example. Nitride film 105 may include a known silicon nitride film.

Interlayer insulating film 108 may be formed on the gates of peripheral region II. Interlayer insulating film 106 in the memory cell region I may have higher concentrations of boron and phosphorus than interlayer insulating film 108 in peripheral region II. Interlayer insulating film 108 in the peripheral region II may have a concentration of boron that is approximately 11 mole percent or less and a concentration of phosphorus that is approximately 6 mole percent or less.

Memory cell region I may have a dense gate pattern. In order to prevent a gate and a contact short, a structure that uses a self aligning contact (SAC) may be generally employed. It may be desired to use the nitride film 105 as an etch stopper to prevent damage to the substrate. Thus, in memory cell region I, the nitride film 105 may not be etched back so that a gate sidewall may not be formed. Nitride film 105 may be dense. Thus, diffusion of boron and phosphorus may be suppressed. In this way, in memory cell region I, boron and phosphorus in interlayer insulating film 106 may be prevented from outdiffusing into the substrate. This may allow the use of an interlayer insulating film 106 containing a relatively high concentration of boron and phosphorus.

In contrast, the nitride film in peripheral region II may be etched back to form side-wall 110 for constructing the lightly doped drain (LDD) structures. However, because peripheral region II may have a relatively coarse gate pattern, there may be no need for the use of a relatively high concentration of boron and phosphorus in interlayer insulating film 108.

In the present embodiment, the concentration of boron and phosphorus in interlayer insulating film 106 in memory cell region I may be approximately 1.3 to 1.8 times the concentration of boron and phosphorus in interlayer insulating film 108 in peripheral region II.

When the concentrations of boron and phosphorus in interlayer insulating film 106 in memory cell region I are approximately 1.3 times higher or more than the concentration of boron and phosphorus in interlayer insulating film 108 in peripheral region II, the filling properties may be higher. By providing concentrations of boron and phosphorus in interlayer insulating film 106 in memory cell region I are approximately 1.8 times higher or less than the concentration of boron and phosphorus in interlayer insulating film 108 in peripheral region II, crystals may be prevented from being formed from dopant ions and/or the formation of phosphoric acid may be prevented.

The surfaces of interlayer insulating film 106 in memory cell region I and interlayer insulating film 108 in peripheral region II may be planarized or flattened. The method of planarization may be any known applicable method.

Although in the present embodiment a silicon substrate may have been used as the substrate, the present invention is not to be limited as such.

Next, a manufacturing method of the present embodiment will be described.

A semiconductor device of the present embodiment may have a manufacturing order so that a gate may be formed. Then a high concentration BPSG interlayer insulating film may be formed followed by the formation of a side-wall for peripheral transistors. Next, a low concentration BPSG interlayer insulating film may be formed followed by process for polishing the interlayer insulating film.

Materials for construction of the semiconductor device of the present embodiment may be set forth, however, the present invention should not be limited as such.

Gate formation in the manufacturing method of a semiconductor device according to the present embodiment will now be described.

Referring to FIG. 4, a cross-sectional view of a portion of a semiconductor device after various processing steps according to an embodiment is set forth. The cross-sectional view of FIG. 4 may illustrate the gate formation in a manufacturing process of a semiconductor device according to the present embodiment.

A shallow trench isolation (STI) 209 structure may be formed on a silicon substrate 201. A gate oxide film 202 may then be formed with thermal oxidation. The gate oxide film 202 may be approximately 7 nm thick. A gate doped polysilicon (DOPOS) film 203 may be formed with a low pressure chemical vapor deposition (LP-CVD) method. The gate DOPOS film 203 may be approximately 100 nm thick. Then, a gate WSi film 204 may be formed with a CVD method. Gate WSi film 204 may be approximately 100 nm thick.

Thereafter, gate patterns (including gate DOPOS film 203 and gate WSi film 204) may be formed with photolithography and etching processes.

After the gate patterning, memory cell region I and peripheral region II may be subjected to ion implantation under proper conditions to form LDD regions of the transistors (not shown).

Next, the formation of the high concentration BPSG interlayer insulating film in the manufacturing method of a semiconductor device according to the present invention will be described.

Referring to FIG. 5, a cross-sectional view of a portion of a semiconductor device after various processing steps according to an embodiment is set forth. The cross-sectional view of FIG. 5 may illustrate the formation of the high concentration BPSG interlayer insulating film in a manufacturing process of a semiconductor device according to the present embodiment.

A nitride film 205 may be formed on the silicon substrate 201 with an LP-CVD method. The nitride film 205 may have a thickness of approximately 50 nm. Thereafter, a high concentration BPSG film 206 may be formed with a normal pressure TEOS (tetraethyl orthosilicate) CVD method. The BPSG film may have a thickness of approximately 700 nm. Because the impurity concentration in the high concentration BPSG film 206 may be high, the filling properties may be excellent. Concentration of boron in the high concentration BPSG film 206 may be higher than approximately 11 mole percent. The concentration of phosphorus may be higher than approximately 6 mole percent. For example, the concentration of boron may be approximately 15 mole percent and the concentration of phosphorus may be approximately 6.5 mole percent.

High concentration BPSG film 206 may then be reflowed by being exposed to heat at approximately 800° C. to 850° C.

Next, the formation of the low concentration BPSG interlayer insulating film in the manufacturing method of a semiconductor device according to the present invention will be described.

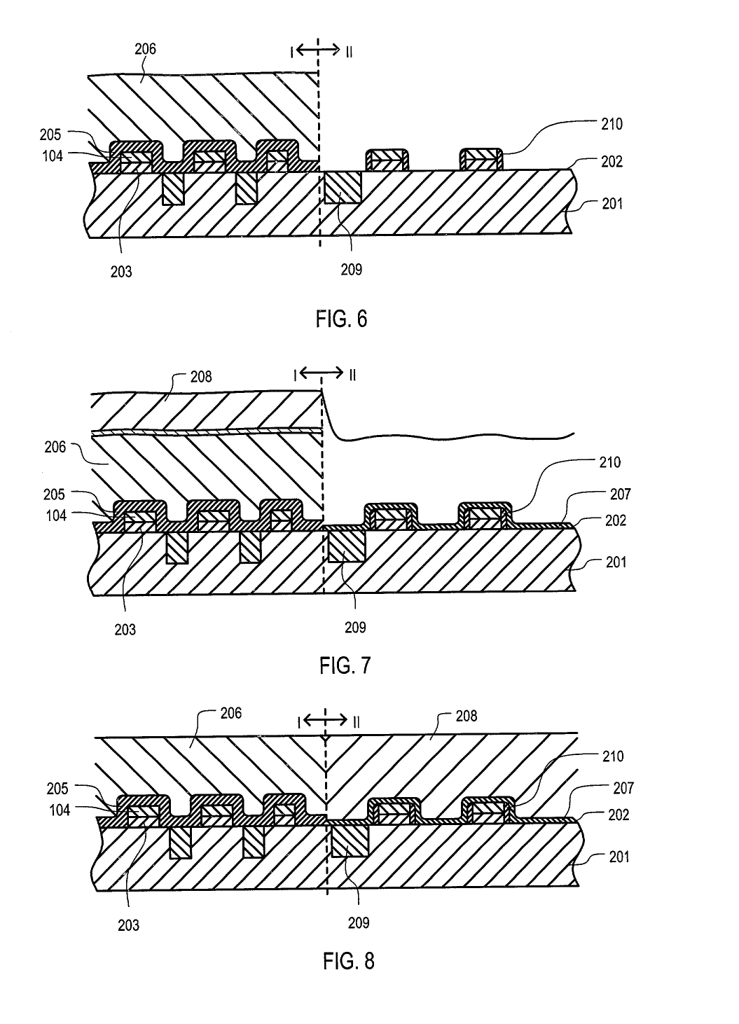

FIGS. 6 to 8 are cross-sectional views of a portion of a semiconductor device after various processing steps according to an embodiment is set forth. The cross-sectional views of FIGS. 6 to 8 may illustrate the formation of the low concentration BPSG interlayer insulating film in a manufacturing process of a semiconductor device according to the present embodiment.

Referring now to FIG. 6, Memory cell region I may be masked so that high concentration BPSG film 206 and nitride film 205 in peripheral region II may be etched using an anisotropic dry etching. In this way, gate side walls 210 may be formed in the peripheral region II.

After the formation of gate side wall 210, the N-type insulated gate field effect transistors (IGFETs) and the P-type IGFETs in the peripheral region may be subjected to ion implantation under proper concentrations to form a source and drain regions for each transistor. Each IGFET may be a metal oxide semiconductor (MOS) FET, as just one example.

Referring now to FIG. 7, an oxide film 207 may then be formed on the surface of the semiconductor device with a normal pressure CVD method. The oxide film 207 may have a thickness of approximately 10 nm. A low concentration BPSG film 208 may be formed with a normal pressure TEOS-CVD method. Low concentration BPSG film 208 film may have a thickness of approximately 500 nm. Concentration of boron in the low concentration BPSG film 208 may be less than approximately 11 mole percent. The concentration of phosphorus may be lower than approximately 6 mole percent. For example, the concentration of boron may be approximately 10 mole percent and the concentration of phosphorus may be approximately 4 mole percent.

Thereafter, low concentration BPSG film 208 may be reflowed by being subjected to heat at 800° C.

Peripheral region II may be considerably coarser in density and may have a wider gate interval than memory cell region I. Thus, an interlayer insulating film may fill spaces more easily in the peripheral region II. Because there is no need for improved filling properties in the interlayer insulating film used in the peripheral region II, a BPSG film having a low concentration of born and phosphorus may be used and low concentration BPSG film 208 may be sufficient.

Referring now to FIG. 8, the surface of the semiconductor device may be flattened or planarized with a chemical mechanical polishing (CMP) method. In this way, the surface of the high concentration BPSG film 206 and low concentration BPSG film 208 may be made essentially flush with each other. The amount of material removed by polishing may be approximately 700 nm, for example.

A dynamic random access memory (DRAM) may be completed with formations of contacts, wirings, and a storage capacitor, although these steps have not been illustrated.

In a manufacturing method in accordance with an embodiment, a semiconductor device may be manufactured in which a high concentration BPSG film 206 may be formed in memory cell region I and a low concentration BPSG film 208 may be formed in a peripheral region II. The memory cell region I may be more finely integrated than the peripheral region II.

The semiconductor device according to the present invention may be one where a gate may be patterned on a substrate. Thereafter, an interlayer insulating film may be formed. In a memory cell region a gate interval may be more densely arranged than in a peripheral region. A nitride film may be formed in the memory cell region before the formation of the interlayer insulating film. This may prevent the outdiffusion of boron and phosphorus into the substrate in the memory cell region. The interlayer insulating film in the memory cell region may have a higher concentration of impurities (such as boron and phosphorus) than the interlayer insulating film in the peripheral region. The boron concentration in the interlayer insulating film in the peripheral region may be less than approximately 11 mole percent and the phosphorus concentration may be less than approximately 6 mole percent. Thus, boron and phosphorus may be prevented from outdiffusing into the substrate in the peripheral region.

The boron concentration and the phosphorus concentration in the interlayer insulating film in the memory cell region may be approximately 1.3 to 1.8 times the concentrations of born and phosphorus in the interlayer insulating film in the peripheral region. In this way, the filling property of the interlayer insulating film formed in the memory cell region may be improved without affecting the peripheral region.

The manufacturing method of a semiconductor device according to the present invention may include a process of patterning a gate on a substrate so that a gate interval in the memory cell region may be more densely formed than in the peripheral region. A nitride film may be formed followed by a process of forming a high concentration interlayer film on the nitride film. The boron concentration of the high concentration interlayer insulating film may be higher than approximately 11 mole percent and the phosphorus concentration may be higher than approximately 6 mole percent. The manufacturing method may also include a process for masking the high concentration interlayer insulating film in the memory cell region so that at least parts of the high concentration interlayer insulating film and nitride film in the peripheral region may be removed by etching. A low concentration interlayer insulating film may then be formed on the high concentration interlayer insulating film in the memory cell region and on the substrate in the peripheral region. The boron concentration in the low concentration interlayer insulating film may be less than approximately 11 mole percent and the phosphorus concentration may be less than approximately 6 mole percent. The surface of the semiconductor device may be flattened or planarized so that the high concentration interlayer insulating film and the low concentration interlayer insulating film may become flush with respect to each other. In this way, a semiconductor device may be manufactured which may have interlayer insulating films having sufficient filling properties while suppressing the diffusion of boron and phosphors into the substrate.

It is understood that the embodiments described above are exemplary and the present invention should not be limited to those embodiments. Specific structures should not be limited to the described embodiments.

Thus, while the various particular embodiments set forth herein have been described in detail, the present invention could be subject to various changes, substitutions, and alterations without departing from the spirit and scope of the invention. Accordingly, the present invention is intended to be limited only as defined by the appended claims.

What is claimed is:

1. A semiconductor device, comprising:
a memory cell region having a plurality of first gates and a first gate interval;
a peripheral region having a plurality of second gates and a second gate interval wherein the first gate interval is denser than the second gate interval;
a nitride film formed on the memory cell region including the plurality of first gates;
a memory cell region interlayer insulating film formed on the memory cell region including the nitride film;
a peripheral region interlayer insulating film formed on the peripheral region; and
the memory cell region interlayer insulating film has a higher concentration of boron and phosphorus than the peripheral region interlayer insulating film.

2. The semiconductor device according to claim 1, wherein:
the concentration of boron in the peripheral region interlayer insulating film is approximately 11 mole percent or less.

3. The semiconductor device of claim 1, wherein:
the concentration of phosphorus in the peripheral region interlayer insulating film is approximately 6 mole percent or less.

4. The semiconductor device of claim 1, wherein:
the concentrations of boron and phosphorus in the memory cell interlayer insulating film is approximately 1.3 to 1.8 times the concentrations of boron and phosphorus in the peripheral region interlayer insulating film.

5. The semiconductor device of claim 1, wherein:
the memory cell region interlayer insulating film fills spaces between the plurality of first gates; and
the peripheral region interlayer insulating film fills spaces between the plurality of second gates.

6. The semiconductor device of claim 1, wherein:
the plurality of second gates include side-wall structures.

7. The semiconductor device of claim 1, wherein:
the plurality of first gates and the plurality of second gates comprise a doped polysilicon film.

8. A method for manufacturing a semiconductor device, comprising the steps of:
patterning a gate on a substrate so that a first gate interval in a memory cell region is more densely arranged than a second gate interval in a peripheral region;
forming a nitride film on the gate;
forming a high dopant concentration interlayer insulating film on the nitride film;
removing at least portions of the nitride film and the high dopant concentration interlayer insulating film in the peripheral region; and
forming a low dopant concentration interlayer insulating film in the memory cell region and the peripheral region wherein the low dopant concentration interlayer insulating film has a lower dopant concentration than the high dopant concentration interlayer insulating film.

9. The method for manufacturing a semiconductor device of claim 8, wherein:
removing at least portions of the nitride film and the high dopant concentration interlayer insulating film includes masking the high impurity concentration interlayer insulating film in the memory cell region.

10. The method for manufacturing a semiconductor device of claim 8, further including the step of:
flattening the high dopant concentration interlayer insulating film and low dopant concentration interlayer insulating film to provide surfaces of the high dopant concentration interlayer insulating film and low dopant concentration interlayer insulating film that are essentially flush with each other.

11. The method for manufacturing a semiconductor device of claim 8, wherein
the high dopant concentration interlayer insulating film has a concentration of boron that is approximately 11 mole percent or higher.

12. The method for manufacturing a semiconductor device of claim 11, wherein:
the high dopant concentration interlayer insulating film has a concentration of phosphorus that is approximately 6 mole percent or higher.

13. The method for manufacturing a semiconductor device of claim 8, wherein:
the low dopant concentration interlayer insulating film has a concentration of boron that is approximately 11 mole percent or less.

14. The method for manufacturing a semiconductor device of claim 13, wherein:
the low dopant concentration interlayer insulating film has a concentration of phosphorus that is approximately 6 mole percent or less.

15. A semiconductor device , comprising:
a first region having a plurality of first gates and a first gate interval;
a second region having a plurality of second gates and a second gate interval wherein the first gate interval is smaller than the second gate interval;
a nitride film formed on the first region including the plurality of first gates;
a first region interlayer insulating film formed on the first region including the nitride film;
a second region interlayer insulating film formed on the second region; and
the first region interlayer insulating film has a higher dopant concentration than the second region interlayer insulating film.

16. The semiconductor device of claim 15, wherein:
the concentration of boron in the second region interlayer insulating film is approximately 11 mole percent or less.

17. The semiconductor device of claim 16, wherein:
the concentration of phosphorus in the second region interlayer insulating film is approximately 6 mole percent or less.

18. The semiconductor device of claim 17, wherein:
the concentration of boron in the first region interlayer insulating film is approximately 11 mole percent or more.

19. The semiconductor device of claim 18, wherein:
the concentration of phosphorus in the first region interlayer insulating film is approximately 6 mole percent or more.

20. The semiconductor device of claim 15, wherein:
the concentrations of boron and phosphorus in the first region interlayer insulating film is approximately 1.3 to 1.8 times the concentrations of boron and phosphorus in the second region interlayer insulating film.
